(19) United States
(12) Patent Application Publication
(10) Pub. No.: US 2025/0259817 A1
(43) Pub. Date: Aug. 14, 2025

(54) SUBSTRATE PROCESSING APPARATUS

(71) Applicant: SAMSUNG ELECTRONICS CO., LTD., Suwon-si (KR)

(72) Inventors: Kyunghyun KIM, Suwon-si (KR); Dougyong SUNG, Suwon-si (KR); Sungho JANG, Suwon-si (KR)

(21) Appl. No.: 19/015,360

(22) Filed: Jan. 9, 2025

(30) Foreign Application Priority Data
Feb. 8, 2024 (KR) 10-2024-0019834

(51) Int. Cl. H01J 37/15; H01J 37/08

(52) U.S. Cl. CPC H01J 37/15; H01J 37/08; H01J 2237/0453; H01J 2237/0473; H01J 2237/1502

(57) ABSTRACT

A substrate processing apparatus includes an upper chamber including an ion source generator, a grid system overlapping the ion source generator in a vertical direction and configured to extract and accelerate an ion source generated by the ion source generator, and a lower chamber, wherein the lower chamber includes, therein, a support configured to support a substrate, a plurality of reflectors arranged in the vertical direction above the support, and a switch configured to switch each of the plurality of reflectors between an on-state and an off-state.

### CROSS-REFERENCE TO RELATED APPLICATION

This application is based on and claims priority under 35 U.S.C. § 119 to Korean Patent Application No. 10-2024-0019834, filed on Feb. 8, 2024, in the Korean Intellectual Property Office, the disclosure of which is incorporated by reference herein in its entirety.

### BACKGROUND

The inventive concept relates to a substrate processing apparatus, and more particularly, to a substrate processing apparatus including a reflector for reflecting an ion beam.

Recently, design rules are changing as semiconductor devices become more highly integrated. Accordingly, process conditions in semiconductor processing equipment are managed more strictly. In response to these demands, performance improvements are continuously being made to plasma processing devices, which mainly focus on technologies for increasing the density of plasma or uniformly distributing plasma.

However, even if performance is improved, the plasma has limitations in its basic characteristics. That is, because plasma is made up of charged particles, there are limitations in performing a semiconductor process using the plasma.

In order to overcome the limitations of processes using plasma, methods have been proposed to perform semiconductor processes by converting ions in plasma into neutral beams. The methods of neutralizing ions include colliding ions with neutral particles, colliding ions with electrons, or colliding ions with a metal plate. Also, research is continuing to optimize the rate at which ions are converted into neutral beams and the directionality of the beam passing through the metal plate while the ions in the plasma are converted into the neutral beams.

### SUMMARY

The inventive concept provides a substrate processing apparatus capable of controlling the neutralization rate, uniformity, and energy distribution of ion beams formed from an upper chamber.

Also, the objects of the inventive concept are not limited to the aforementioned object, but other objects not described herein will be clearly understood by those skilled in the art from the following description.

In order to achieve the above object, the inventive concept may provide a substrate processing apparatus as described herein.

According to an aspect of the inventive concept, there is provided a substrate processing apparatus including an upper chamber including an ion source generator, a grid system overlapping the ion source generator in a vertical direction and configured to extract and accelerate an ion source generated by the ion source generator, and a lower chamber, wherein the lower chamber includes, therein, a support configured to support a substrate, a plurality of reflectors arranged in the vertical direction above the support, and a switch configured to switch each of the plurality of reflectors between an on-state and an off-state.

According to another aspect of the inventive concept, there is provided a substrate processing apparatus including an upper chamber including an ion source generator configured to form an ion source, a grid system below the ion source generator and configured to extract and accelerate the ion source, and a lower chamber below the upper chamber and including a support configured to support a substrate, a plurality of reflectors arranged in a vertical direction above the support, and a switch configured to switch each of the plurality of reflectors between an on-state and an off-state, wherein any one of the reflectors in the on-state overlaps the grid system in the vertical direction, and any one of the reflectors in the off-state does not overlap the grid system in the vertical direction, and a plurality of grooves are formed in each of the plurality of reflectors.

According to another aspect of the inventive concept, there is provided a substrate processing apparatus including an upper chamber including an ion source generator configured to form an ion source, a grid system below the ion source generator and configured to extract and accelerate the ion source, and a lower chamber below the upper chamber and including a support configured to support a substrate, a plurality of reflectors arranged in a vertical direction above the support, a switch configured to switch each of the plurality of reflectors between an on-state and an off-state, and a holder configured to fix each of the plurality of reflectors, wherein a width of the lower chamber in a first horizontal direction is greater than a width of the upper chamber in the first horizontal direction, any one of the reflectors in the on-state overlaps the grid system in the vertical direction, and any one of the reflectors in the off-state does not overlap the grid system in the vertical direction, and wherein a plurality of grooves are formed in each of the plurality of reflectors, and the switch is configured to independently rotate each of the plurality of reflectors.

### BRIEF DESCRIPTION OF THE DRAWINGS

Example embodiments will be more clearly understood from the following detailed description taken in conjunction with the accompanying drawings in which:

FIGS. 1A and 1B are cross-sectional views showing a substrate processing apparatus according to embodiments;

FIGS. 2A and 2B are cross-sectional views showing paths of ion beams in the substrate processing apparatus according to embodiments;

FIG. 3 is a schematic view showing a switch according to embodiments;

FIG. 4 is a schematic view showing a switch according to embodiments;

FIG. 5 is a cross-sectional view showing a groove of a reflector according to embodiments;

FIG. 6 is a cross-sectional view showing a groove of a reflector according to embodiments;

FIG. 7 is a cross-sectional view showing a groove of a reflector according to embodiments;

FIGS. 8A and 8B are cross-sectional views showing directionality of ion beams in a substrate processing apparatus according to embodiments;

FIG. 9 is a plan view schematically showing a reflector according to embodiments;

FIG. 10 is a plan view schematically showing a reflector according to embodiments; and

FIG. 11 is a cross-sectional view schematically showing a substrate processing apparatus according to embodiments.

### DETAILED DESCRIPTION

Hereinafter, example embodiments are described in detail with reference to the accompanying drawings. The same reference numerals are given to the same elements in the drawings, and repeated descriptions thereof may be omitted in the interest of brevity.

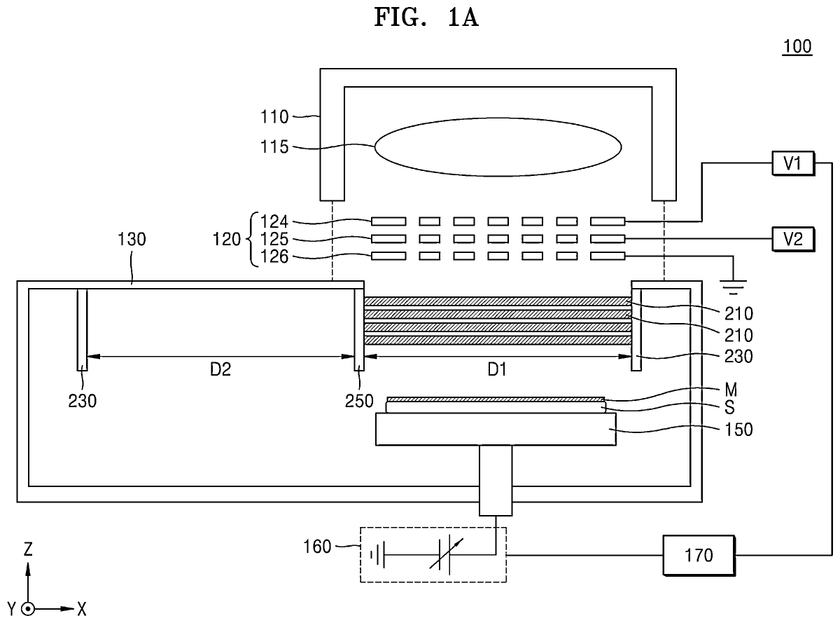

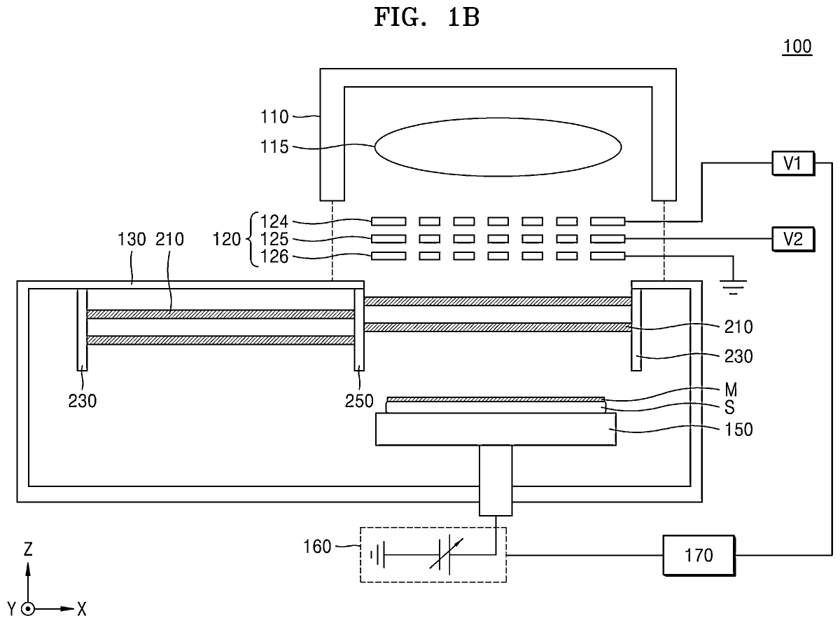

FIGS. 1A and 1B are cross-sectional views showing a substrate processing apparatus 100 according to embodiments.

Referring to FIGS. 1A and 1B, the substrate processing apparatus 100 may include an upper chamber 110, a grid system 120, and a lower chamber 130. The upper chamber 110 may function as a housing having a space therein to form an ion source. An ion source generator 115 may be provided inside the upper chamber 110. The ion source generator 115 may be located in a certain region inside the upper chamber 110. For example, the ion source generator 115 may form plasma. According to embodiments, the ion source generator 115 may form capacitive coupled plasma (CCP), electron cyclotron resonance (ECR) plasma (ECR plasma), helicon plasma, or inductive coupled plasma (ICP). Furthermore, the ion source generator 115 may form plasma in numerous modified forms suitable for each process.

The grid system 120 may be located below the ion source generator 115. In some embodiments, the grid system 120 may be provided inside the upper chamber 110. The grid system 120 may include a first grid unit 124, a second grid unit 125, and a third grid unit 126. The first grid unit 124 may be located below the ion source generator 115. In the drawings, when the direction in which the first grid unit 124 and the ion source generator 115 are spaced apart from each other is defined as a vertical direction Z, each of an X-axis direction and a Y-axis direction may be understood as a direction perpendicular to the vertical direction Z. Also, the X-axis direction and the Y-axis direction may be perpendicular to each other.

Also, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

The second grid unit 125 may be spaced apart from the ion source generator 115 in the vertical direction Z with the first grid unit 124 therebetween. The third grid unit 126 may be spaced apart from the ion source generator 115 in the vertical direction Z with the first grid unit 124 and the second grid unit 125 therebetween. According to embodiments, the first grid unit 124, the second grid unit 125, and the third grid unit 126 may be spaced apart from each other in the vertical direction Z. Also, the first grid unit 124, the second grid unit 125, and the third grid unit 126 may overlap each other in the vertical direction Z.

The first grid unit 124 and the second grid unit 125 may have different electric potentials. According to embodiments, a grid power supply device capable of applying certain voltages to the first and second grid units 124 and 125 may be provided so that the first grid unit 124 and the second grid unit 125 have different electric potentials. For example, a first grid power supply device V1 may be connected to the first grid unit 124 and a second grid power supply device V2 may be connected to the second grid unit 125. The first and second grid power supply devices V1 and V2 may respectively apply a positive voltage to the first grid unit 124 and a negative voltage to the second grid unit 125. Accordingly, positive process ions may be extracted and accelerated from the ion source generator 115.

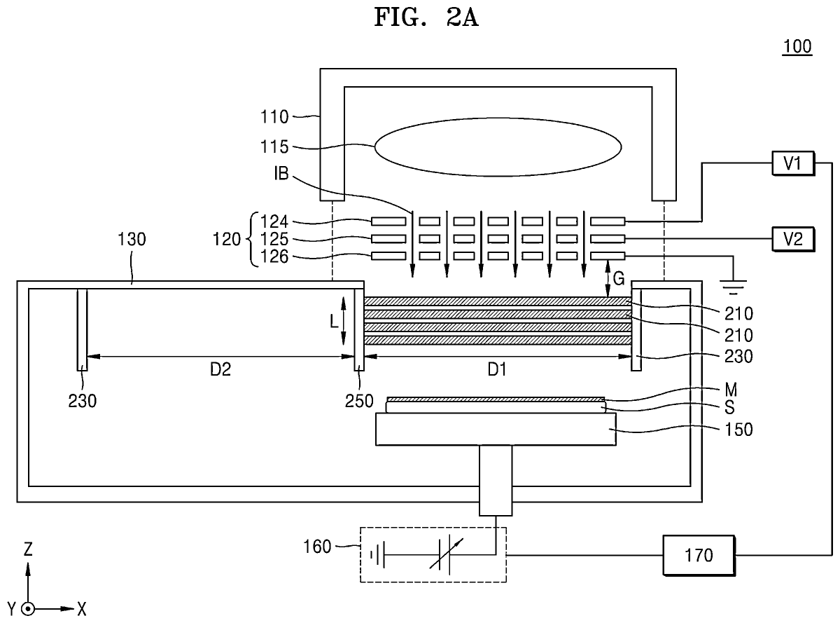

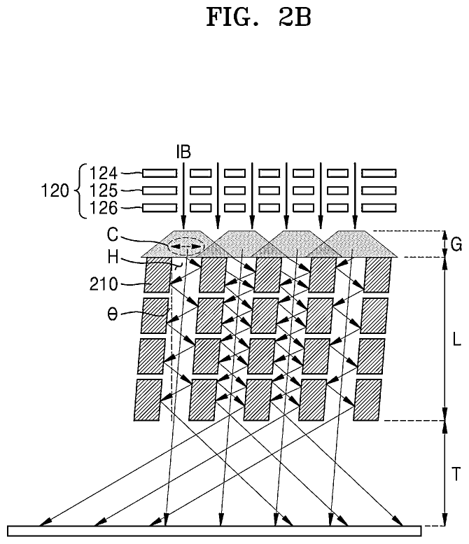

The third grid unit 126 may appropriately maintain the directionality of the positive process ions that are extracted and accelerated from the first grid unit 124 and the second grid unit 125. Also, the third grid unit 126 may be grounded. In this specification, it has been described that three grid units are provided in the grid system 120, but the grid system 120 is not limited thereto. The grid system 120 may include one or more grid units. In addition, the process ions used herein may be understood as an ion beam IB (see FIGS. 2A and 2B), which is described below with reference to FIGS. 2A and 2B.

The lower chamber 130 may be located below the upper chamber 110 and the grid system 120. According to embodiments, the length or width of the lower chamber 130 in the first horizontal direction X may be greater than the length or width of the upper chamber 110 in the first horizontal direction X.

A plurality of reflectors 210, a holder 230, a switch 250, and a support 150 may be provided inside the lower chamber 130. According to embodiments, the plurality of reflectors 210 may neutralize the process ions extracted and accelerated from the grid system 120 into neutral beams. For example, the process ions may be converted into neutral beams while passing through the plurality of reflectors 210.

According to embodiments, the plurality of reflectors 210 may be at different vertical levels. The plurality of reflectors 210 may move on the X-Y plane. For example, as shown in FIG. 1A, the plurality of reflectors 210 may be arranged side by side in the vertical direction Z. Also, the plurality of reflectors 210 may overlap each other in the vertical direction Z. Also, each of the plurality of reflectors 210 may overlap the grid system 120 in the vertical direction Z.

On the other hand, some of the plurality of reflectors 210 may be moved by the switch 250 so that some of reflectors 210 do not overlap the grid system 120 in the vertical direction Z. For example, as shown in FIG. 1B, the reflectors 210 provided at the second and fourth positions from the top among the four reflectors 210 may be moved to the opposite side by the switch 250. Also, the moved reflectors 210 may not overlap the grid system 120 in the vertical direction Z.

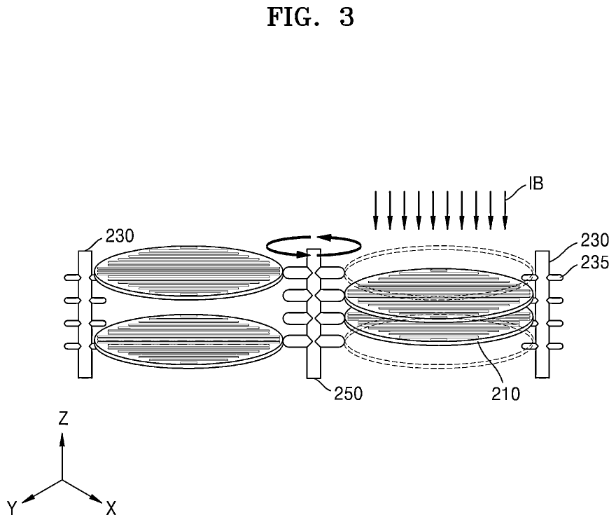

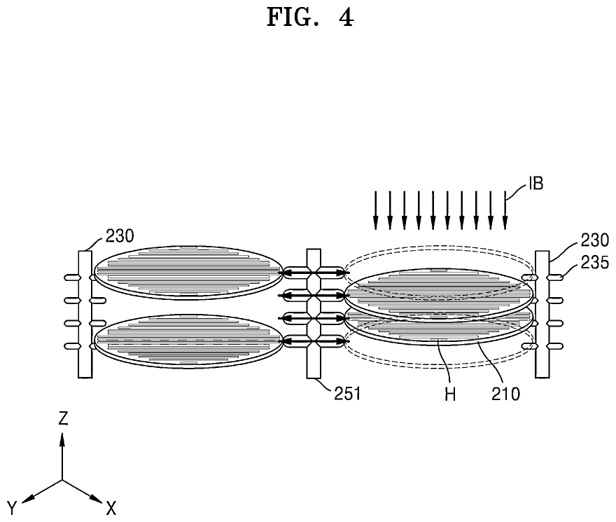

Also, when the state in which the reflector 210 overlaps the grid system 120 in the vertical direction Z is defined as an on-state and the state in which the reflector 210 does not overlap the grid system 120 in the vertical direction Z is defined as an off-state, the switch 250 may be configured to switch each of the plurality of reflectors 210 between the on-state and the off-state. The switch 250 is described in detail below with reference to FIGS. 3 and 4. Also, the number of reflectors 210 is shown as four in the drawings, but the number of reflectors 210 is not limited thereto. The number of reflectors 210 may be two or more.

The holder 230 may be configured to fix the reflector 210. According to embodiments, a plurality of holders 230 may be provided. The plurality of holders 230 may be spaced apart from each other in the first horizontal direction X with the switch 250 therebetween. According to embodiments, the holder 230 located on the right side of the switch 250 may fix the reflector 210 in the on-state. In other words, the holder 230 adjacent to the grid system 120 may fix the reflector 210 in the on-state. On the other hand, the holder 230 on the left side of the switch 250 may fix the reflector 210 in the off-state.

The length or width of the lower chamber 130 in the first horizontal direction X may be at least twice the length or width of the reflector 210 in the first horizontal direction X so as to accommodate the reflectors 210 that switch between the on-state and the off-state. In addition, according to embodiments, as shown in FIG. 1A, a distance D1 from the switch 250 to the holder 230 located on the right side may be substantially the same as a distance D2 from the switch 250 to the holder 230 located on the left side.

The support 150 may be configured to support a substrate S. The support 150 may be located below the reflector 210. The support 150 may overlap the grid system 120 in the vertical direction Z. The substrate S may be placed on the upper surface of the support 150. The substrate S may include a wafer for manufacturing a semiconductor device, a thin film display, or an ultrafine structure. A mask M may be provided on the upper surface of the substrate S.

According to embodiments, the substrate processing apparatus 100 may further include a power supply device 160. The power supply device 160 may be configured to supply power to the support 150 so that the support 150 has a polarity. For example, when the remaining process ions provided to the support 150 include positive ions, the power supply device 160 may supply a voltage so that the support 150 has a positive polarity. Also, the power supply device 160 may make the support 150 have a greater electric potential than the remaining process ions. Also, the remaining process ions as used herein may be defined as ions that have not been converted into neutral beams among the process ions that have passed through the reflectors 210. The voltage applied to the support 150 by the power supply device 160 may be greater than the voltage applied to the first grid unit 124 by the first grid power supply device V1. A controller 170 connected to the power supply device 160 and the first grid power supply device V1 may be provided. The controller 170 may control the power supply device 160 and the first grid power supply device V1 and apply a voltage greater than that of the first grid unit 124 to the support 150.

FIGS. 2A and 2B are cross-sectional views showing paths of ion beams in the substrate processing apparatus 100 according to embodiments. Hereinafter, repeated descriptions as those given with reference to FIGS. 1A and 1B may be omitted in the interest of brevity, and the description focuses on the differences.

Each of ion beams IB formed in the ion source generator 115 may pass through the grid system 120 and be provided to the reflector 210. The ion beams IB provided to the reflector 210 may pass through the reflector 210 in the vertical direction Z along grooves H formed in the reflector 210. Also, the ion beams IB may be reflected while passing through the grooves H of the reflector 210. For example, as shown in FIG. 2B, the ion beam IB may collide with the sidewall of the reflector 210.

While the ion beams IB pass through the reflector 210 and are emitted to the substrate S, the rate of conversion to neutral beams, the directionality of the neutral beams, the energy distribution of the neutral beams, or the like may vary depending on various parameters. For example, as a distance G in the vertical direction Z between the grid system 120 and the reflector 210 increases, the rate at which the ion beams IB are converted into the neutral beams may increase. Also, as a length L of the reflectors 210 in the vertical direction Z increases, the energy of the neutral beams may become more uniform or the rate at which the ion beams IB are converted into the neutral beams may increase. In addition, the direction of the neutral beam may have isotropic characteristics depending on an angle θ at which each of grooves H of the reflector 210 is tilted or inclined (e.g., relative to vertical).

In the substrate processing apparatus 100 according to the inventive concept as described above with reference to FIGS. 1A and 1B, the plurality of reflectors 210 may be switched between the on-state and the off-state by the switch 250. Accordingly, various parameters of the reflector 210 may be adjusted without any specific replacement of the reflector 210.

For example, when all of the plurality of reflectors 210 are switched to the on-state by the switch 250, the ion beam IB passes through all of the reflectors 210. Accordingly, the length L of the reflector 210 in the vertical direction Z, which is one of the parameters of the reflector 210, may increase. In other words, when all reflectors 210 are switched to the on-state and the reflectors 210 in the on-state may be regarded as a single reflector 210, the reflector 210 may have a relatively large length L in the vertical direction Z. On the other hand, when the switch 250 switches the at least one reflector 210 to the off-state, the length L of the reflector 210 in the vertical direction Z may decrease. In other words, when at least one reflector 210 is switched to the off-state and the remaining reflectors 210 in the on-state may be regarded as a single reflector 210, the reflector 210 may have a relatively small length L in the vertical direction Z.

In addition, when the reflector 210 located at the uppermost position among the plurality of reflectors 210 (hereinafter, referred to as the uppermost reflector 210) is switched to the off-state by the switch 250, the distance G in the vertical direction Z between the grid system 120 and the reflector 210, which is one of the parameters of the reflector 210, may increase. Furthermore, when only the reflector 210 located at the lowermost position among the plurality of reflectors 210 is switched to the on-state by the switch 250, the distance G in the vertical direction Z between the grid system 120 and the reflector 210 may increase to its maximum value.

In addition, when the grooves H of each of the plurality of reflectors 210 are formed at various angles θ, for example, when the angle θ of the groove H of the uppermost reflector 210 is different from the angle θ of a groove H of another reflector 210 located just below the uppermost reflector 210, a process may be performed by switching only the reflectors 210 having the desired angles θ to the on-state.

In addition, when the grooves H of each of the plurality of reflectors 210 have various widths C, for example, when the width C of a groove H of the uppermost reflector 210 is different from the width C of a groove H of another reflector 210 located just below the uppermost reflector 210, a process may be performed by switching only the reflectors 210 having the desired widths C to the on-state.

As described above, in the substrate processing apparatus 100 according to the inventive concept, each of the plurality of reflectors 210 may be switched between the on-state and the off-state by the switch 250 so as to control the ion beams IB passing through the reflectors 210 to have desired conditions. Also, inconveniences, such as replacing the reflector 210 to control the conditions of the ion beams IB, may be eliminated.

FIG. 3 is a schematic view showing a switch 250 according to embodiments. FIG. 4 is a schematic view showing a switch 251 according to embodiments. Hereinafter, repeated descriptions as those given with reference to FIGS. 1A to 2B may be omitted in the interest of brevity, and the description focuses on the differences.

Referring to FIGS. 3 and 4, switches 250 and 251 may switch each of the plurality of reflectors 210 between the on-state and the off-state. Also, the ion beams IB may be provided to the reflectors 210 in the on-state, but the ion beams IB may not be provided to the reflectors 210 in the off-state.

Each of the plurality of reflectors 210 may be fixed by the holder 230. According to embodiments, each of the holders 230 may have protrusions 235 extending in the first horizontal direction X. Each of the reflectors 210 may be supported by the protrusion 235 of the holder 230.

The switches 250 and 251 may be coupled to and separated from each of the reflectors 210. The switches 250 and 251 may be configured to attach and detach the reflectors 210. For example, when replacing the reflector 210, the reflector 210 coupled to the switches 250 and 251 is separated from the switches 250 and 251 and a new reflector 210 is coupled to the switches 250 and 251. Accordingly, replacement of the reflector 210 may be performed.

According to embodiments, the switch 250 may switch the reflector 210 between the on-state and the off-state using a rotation method. As shown in FIG. 3, the switch 250 may control the on-state and the off-state of the plurality of reflectors 210 by rotating each of the reflectors 210 on the X-Y plane.

According to embodiments, the switch 251 may switch the reflector 210 between the on-state and the off-state using a sliding method. As shown in FIG. 4, the switch 251 may control the on-state and the off-state of the reflector 210 by moving the plurality of reflectors 210 along a straight line in the first horizontal direction X.

The method by which the switches 250 and 251 control the on-state and the off-state of the reflector 210 according to the inventive concept is not limited to the above, and the on-state and off-state of the reflector 210 may be controlled in various manners.

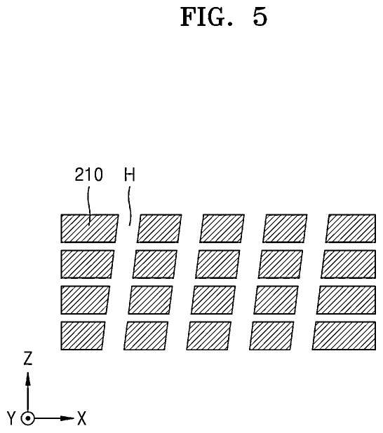

FIG. 5 is a cross-sectional view showing a groove H of a reflector 210 according to embodiments. Hereinafter, repeated descriptions as those given with reference to FIGS. 1A to 4 may be omitted in the interest of brevity, and the description focuses on the differences.

Referring to FIG. 5, four reflectors 210 may be provided. However, the number of reflectors 210 above is only one example, and the inventive concept is not limited thereto. A plurality of grooves H may be formed in each of the reflectors 210.

According to embodiments, the groove H of the reflector 210 may be formed to have an inclination when viewed from the X-Z plane. For example, with reference to FIG. 5, the groove H of the reflector 210 may be inclined relative to the Z axis when viewed from the X-Z plane. Also, the grooves H formed in the plurality of reflectors 210 at different vertical levels are inclined at the same angle relative to the Z axis when viewed from the X-Z plane. However, the locations at which the grooves H are formed may be different from each other in the reflectors 210 at different vertical levels. Specifically, with respect to the groove H formed in the reflector 210 located at the uppermost position, the groove H formed in the reflector 210 located just below the uppermost reflector 210 may be formed at a different position from the groove H formed in the uppermost reflector 210. In some embodiments, the lower surface of the groove H of the uppermost reflector 210 may overlap the upper surface of the groove H of the reflector 210 located just below the uppermost reflector 210 in the vertical direction Z. On the other hand, the upper surface of the groove H of the uppermost reflector 210 and the upper surface of the groove H of the reflector 210 located just below the uppermost reflector 210 may partially overlap each other or may not completely overlap each other. Accordingly, when viewed from the X-Z plane, a continuous diagonal shape may be formed by combining the shapes of the grooves H of the reflectors 210 at different vertical levels. In the same sense, the grooves H formed in the plurality of reflectors 210 at different vertical levels may have a continuous direction.

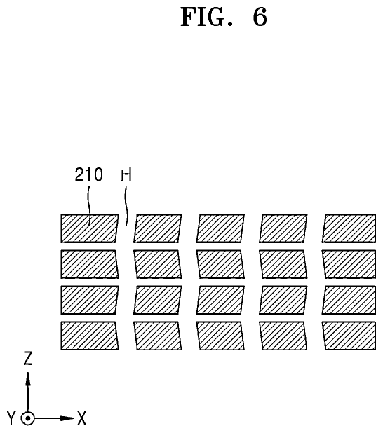

FIG. 6 is a cross-sectional view showing a groove H of a reflector 210 according to embodiments. Hereinafter, repeated descriptions as those given with reference to FIGS. 1A to 5 may be omitted in the interest of brevity, and the description focuses on the differences.

Referring to FIG. 6, four reflectors 210 may be provided. However, the number of reflectors 210 above is only one example, and the inventive concept is not limited thereto. A plurality of grooves H may be formed in each of the reflectors 210.

According to embodiments, the groove H of the reflector 210 may be formed to have an inclination when viewed from the X-Z plane. However, unlike FIG. 5, the plurality of reflectors 210 may have grooves H having different slopes or inclination angles according to the vertical levels. The slope used herein may represent the degree to which the groove H is inclined on the X-Z plane. In some embodiments, the reflectors 210 provided at the first and third locations from the top among the plurality of reflectors 210 may have the same first slope, and the reflectors 210 provided at the second and fourth locations from the top may have the same second slope. Also, the first slope may be different from the second slope. Also, both the first slope and the second slope may represent the degree to which the groove H of the reflector 210 is inclined on the X-Z plane.

In some embodiments, the first slope and the second slope may be symmetrical to each other about the Z-axis. Also, when the grooves H of the plurality of reflectors 210 are viewed from the X-Z plane, the overall shape of the grooves H may be a lightning bolt or zig-zag shape, as shown in FIG. 6. In addition, in some embodiments, the plurality of reflectors 210 at different vertical levels may all have different slopes. In some embodiments, only one of the plurality of reflectors 210 at different vertical levels may have a different slope.

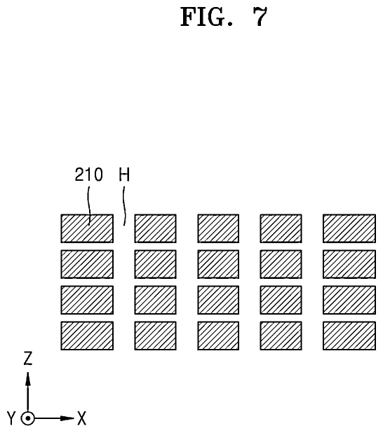

FIG. 7 is a cross-sectional view showing a groove H of a reflector 210 according to embodiments. Hereinafter, repeated descriptions as those given with reference to FIGS. 1A to 6 may be omitted in the interest of brevity, and the description focuses on the differences.

Referring to FIG. 7, four reflectors 210 may be provided. However, the number of reflectors 210 above is only one example, and the inventive concept is not limited thereto. A plurality of grooves H may be formed in each of the reflectors 210.

According to embodiments, the grooves H formed in each of the plurality of reflectors 210 may all extend in the vertical direction Z. For example, the groove H formed in each of the plurality of reflectors 210 may have a shape extending parallel to the Z axis when viewed from the X-Z plane.

In some embodiments, the grooves H formed in some of the reflectors 210 at different vertical levels have a shape extending parallel to the Z axis when viewed from the X-Z plane, and the grooves H formed in the other reflectors 210 may have a shape inclined to the Z axis when viewed from the X-Z plane.

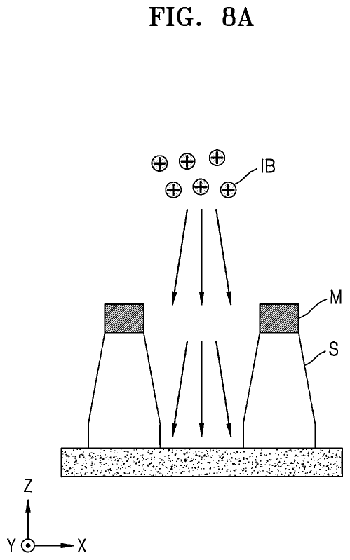

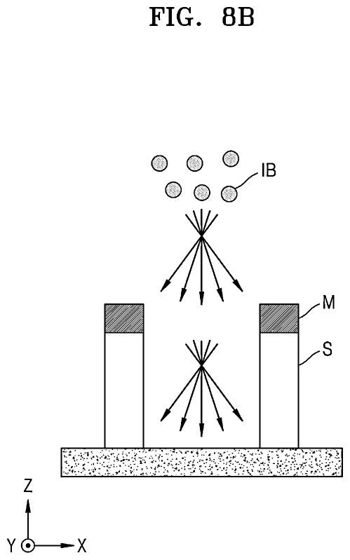

FIGS. 8A and 8B are cross-sectional views showing directionality of ion beams IB in a substrate processing apparatus according to embodiments. Hereinafter, repeated descriptions as those given with reference to FIGS. 1 to 7 may be omitted in the interest of brevity, and the description focuses on the differences.

Referring to FIGS. 2A, 8A, and 8B, the ion beams IB to be emitted toward the substrate S may pass through a pattern formed in the mask M and collide with the substrate S. Also, when the ion beams IB do not pass through the reflectors 210, the ion beams IB may be emitted to the substrate S with a constant direction, as shown in FIG. 8A. In this case, a portion of the substrate S that is etched by the ion beams IB may have a tapered shape. For example, the etched portion of the substrate S may have a horizontal width that is reduced from the top to the bottom.

On the other hand, when the ion beams IB pass through the reflectors 210, the ion beams IB are converted into neutral beams. Also, the neutral beams may have isotropic characteristics. In this case, the etched portion of the substrate S may have a shape extending straight in the vertical direction Z. For example, the etched portion of the substrate S may have a horizontal width that is constant from the top to the bottom.

In the substrate processing apparatus 100 according to the inventive concept, when all of the reflectors 210 are switched to the off-state, the ion beams IB that have passed through the grid system 120 may be directly emitted onto the substrate S. However, when at least one reflector 210 is switched to the on-state, the neutral beam that has passed through the reflector 210 may be emitted, in an isotropic state, onto the substrate S. That is, in the substrate processing apparatus 100 according to the inventive concept, the etched portion of the substrate S may have a desired shape by adjusting the on-state and off-state of the reflector 210 above the substrate S.

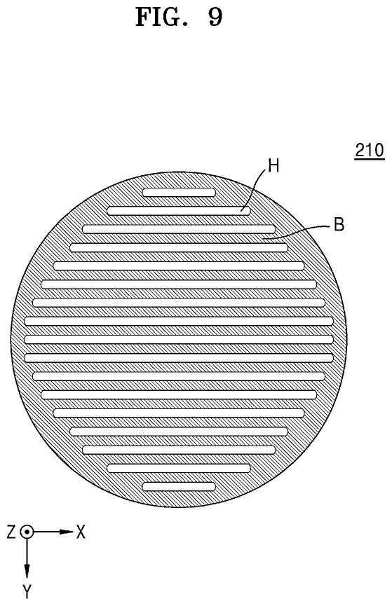

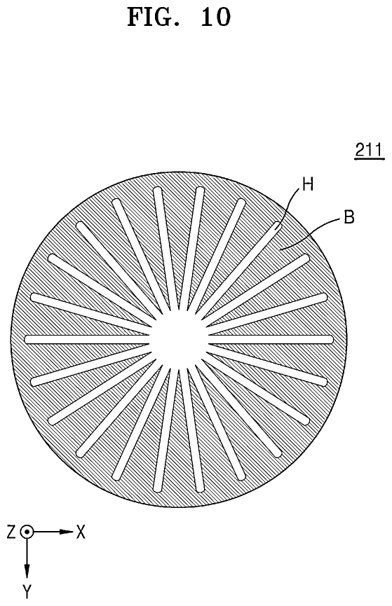

FIG. 9 is a plan view schematically showing a reflector 210 according to embodiments. FIG. 10 is a plan view schematically showing a reflector 211 according to embodiments. Hereinafter, repeated descriptions as those given with reference to FIGS. 1A to 8B may be omitted in the interest of brevity, and the description focuses on the differences.

Referring to FIGS. 9 and 10, each of the reflectors 210 and 211 may include a body B and a groove H. The groove H passes through the body B in the vertical direction Z. When viewed from the Y-Z plane in FIG. 9 or when viewed laterally in any direction X or Y in FIG. 10, the groove H may be parallel to the Z-axis or may extend at a certain angle relative to the Z-axis. Since this is substantially the same as those given with reference to FIGS. 1A to 8B, details thereof are omitted in the interest of brevity.

According to embodiments, the reflector 210 may have a plurality of grooves H extending parallel to each other. For example, as shown in FIG. 9, the plurality of grooves H formed in the reflector 210 may have a shape extending in the first horizontal direction X when viewed in the vertical direction Z. Also, the plurality of grooves H may be spaced apart from each other in the second horizontal direction Y.

According to embodiments, the reflector 211 may have a plurality of grooves H extending (radially outwardly) from the center toward the side surface or edge of the reflector 211. For example, as shown in FIG. 10, the plurality of grooves H formed in the reflector 211 may meet each other at the center of the reflector 211 and form a certain angle relative to each other on the X-Y plane.

The shape of the grooves H formed in the reflectors 210 and 211 is not limited thereto, and the grooves H having various shapes may be formed in the reflectors 210 and 211.

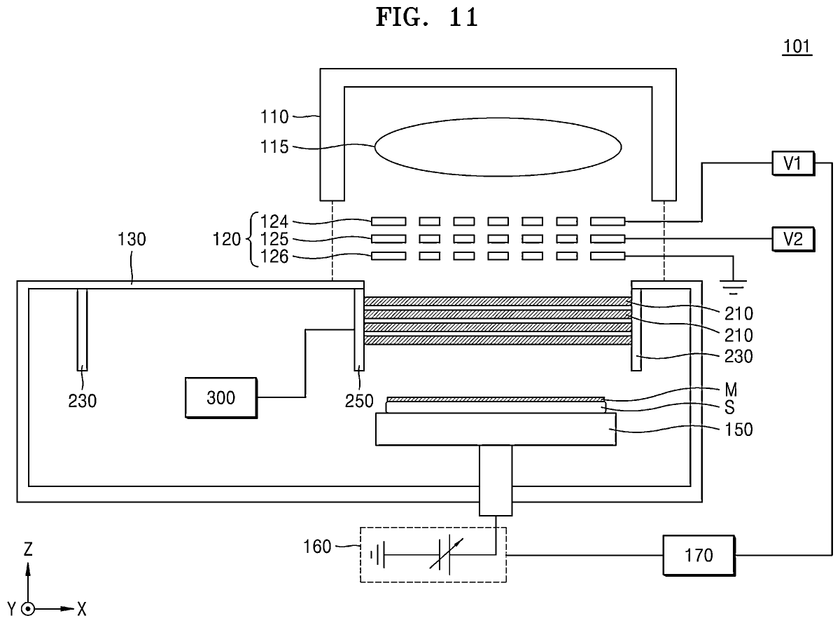

FIG. 11 is a cross-sectional view schematically showing a substrate processing apparatus 101 according to embodiments. Hereinafter, repeated descriptions as those given with reference to FIGS. 1A to 10 may be omitted in the interest of brevity, and the description focuses on the differences.

Referring to FIG. 11, the substrate processing apparatus 101 may include an upper chamber 110, a grid system 120, and a lower chamber 130. The upper chamber 110 may function as a housing having a space therein to form an ion source. An ion source generator 115 may be provided inside the upper chamber 110. The ion source generator 115 may be located in a certain region inside the upper chamber 110. The grid system 120 may be located below the ion source generator 115. In some embodiments, the grid system 120 may be provided inside the upper chamber 110. The grid system 120 may include a first grid unit 124, a second grid unit 125, and a third grid unit 126.

The lower chamber 130 may be located below the upper chamber 110 and the grid system 120. A plurality of reflectors 210, a holder 230, a switch 250, a support 150, and a controller 300 may be provided inside the lower chamber 130.

The controller 300 may be configured to control the switch 250. According to embodiments, the controller 300 may control the switch 250 to switch each of the plurality of reflectors 210 between the on-state and the off-state.

The controller 300 may be provided as hardware, firmware, software, or any combination thereof. For example, the controller 300 may include a computing devices, such as a workstation computer, a desktop computer, a laptop computer, and a tablet computer. The controller 300 may include a simple controller, a complex processor, such as a microprocessor, a central processing unit (CPU), and a graphics processing unit (GPU), a processor configured by software, dedicated hardware, or firmware. The controller 300 may be configured by, for example, a general-purpose computer, or application-specific hardware, such as a digital signal processor (DSP), a field programmable gate array (FPGA), and an application specific integrated circuit (ASIC). The controller 300 may be configured by instructions which are stored on a machine-readable medium and read and executed by one or more processors. Here, the machine-readable medium may include any mechanism for storing and/or transmitting information in a form readable by a machine (e.g., a computing device). For example, the machine-readable media may include read only memory (ROM), random access memory (RAM), magnetic disk storage media, optical storage media, flash memory devices, electrical, optical, acoustic, or other forms of radio signals (e.g., carrier waves, infrared signals, digital signals, etc.), and any other signals.

While the inventive concept has been particularly shown and described with reference to example embodiments thereof, it will be understood that various changes in form and details may be made therein without departing from the scope of the following claims.

What is claimed is:

1. A substrate processing apparatus comprising:
an upper chamber comprising an ion source generator;
a grid system overlapping the ion source generator in a vertical direction and configured to extract and accelerate an ion source generated by the ion source generator; and
a lower chamber,
wherein the lower chamber comprises, therein, a support configured to support a substrate, a plurality of reflectors arranged in the vertical direction above the support, and a switch configured to switch each of the plurality of reflectors between an on-state and an off-state.

2. The substrate processing apparatus of claim 1, wherein the switch is configured to independently rotate each of the plurality of reflectors.

3. The substrate processing apparatus of claim 1, wherein the switch is configured to move each of the plurality of reflectors in a first horizontal direction using a sliding method.

4. The substrate processing apparatus of claim 1, wherein a width of the lower chamber in a first horizontal direction is greater than a width of the upper chamber in the first horizontal direction.

5. The substrate processing apparatus of claim 1, further comprising a holder configured to fix each of the plurality of reflectors.

6. The substrate processing apparatus of claim 1, wherein the reflector(s) in the on-state overlap(s) the grid system in the vertical direction, and the reflector(s) in the off-state do(es) not overlap the grid system in the vertical direction.

7. The substrate processing apparatus of claim 1, wherein a groove through which the ion source passes is defined in each of the plurality of reflectors, and
the grooves respectively defined in the plurality of reflectors have the same slope relative to the vertical direction.

8. The substrate processing apparatus of claim 1, wherein a groove through which the ion source passes is defined in each of the plurality of reflectors,
at least one of the plurality of reflectors has a groove with a first slope relative to the vertical direction, and
at least one other of the plurality of reflectors has a groove with a second slope relative to the vertical direction.

9. The substrate processing apparatus of claim 1, wherein a groove through which the ion source passes is defined in each of the plurality of reflectors, and
the groove defined in each of the plurality of reflectors extends in the vertical direction.

10. The substrate processing apparatus of claim 1, wherein a plurality of grooves through which the ion source passes are defined in each of the plurality of reflectors, and
the plurality of grooves defined in at least one of the plurality of reflectors each have a shape extending in a first horizontal direction and are spaced apart from each other in a second horizontal direction when viewed in the vertical direction.

11. The substrate processing apparatus of claim 1, wherein a plurality of grooves through which the ion source passes are defined in each of the plurality of reflectors, and
the plurality of grooves formed in at least one of the plurality of reflectors are defined at a certain angle relative to each other on an X-Y plane.

12. The substrate processing apparatus of claim 1, wherein the switch is configured to be coupled to or separated from each of the plurality of reflectors.

13. A substrate processing apparatus comprising:
an upper chamber comprising an ion source generator configured to form an ion source;
a grid system below the ion source generator and configured to extract and accelerate the ion source; and
a lower chamber below the upper chamber and comprising a support configured to support a substrate, a plurality of reflectors arranged in a vertical direction above the support, and a switch configured to switch each of the plurality of reflectors between an on-state and an off-state,
wherein any one of the reflectors in the on-state overlaps the grid system in the vertical direction, and any one of the reflectors in the off-state does not overlap the grid system in the vertical direction, and
a plurality of grooves are formed in each of the plurality of reflectors.

14. The substrate processing apparatus of claim 13, wherein a width of the lower chamber in a first horizontal direction is greater than a width of the upper chamber in the first horizontal direction.

15. The substrate processing apparatus of claim 13, wherein the switch is configured to independently rotate each of the plurality of reflectors.

16. The substrate processing apparatus of claim 13, wherein the switch is configured to move each of the plurality of reflectors in a first horizontal direction using a sliding method.

17. The substrate processing apparatus of claim 13, wherein at least one of the plurality of reflectors has a groove with a first slope relative to the vertical direction, and
at least one other of the plurality of reflectors has a groove with a second slope relative to the vertical direction.

18. A substrate processing apparatus comprising:
an upper chamber comprising an ion source generator configured to form an ion source;
a grid system below the ion source generator and configured to extract and accelerate the ion source; and
a lower chamber below the upper chamber and comprising a support configured to support a substrate, a plurality of reflectors arranged in a vertical direction above the support, a switch configured to switch each of the plurality of reflectors between an on-state and an off-state, and a holder configured to fix each of the plurality of reflectors,
wherein a width of the lower chamber in a first horizontal direction is greater than a width of the upper chamber in the first horizontal direction,
any one of the reflectors in the on-state overlaps the grid system in the vertical direction, and any one of the reflectors in the off-state does not overlap the grid system in the vertical direction, and
wherein a plurality of grooves are formed in each of the plurality of reflectors, and
the switch is configured to independently rotate each of the plurality of reflectors.

19. The substrate processing apparatus of claim 18, wherein each of the plurality of grooves formed in at least one of the plurality of reflectors has an elongated shape extending in the first horizontal direction when viewed in the vertical direction, and
the plurality of grooves are spaced apart from each other in a second horizontal direction.

20. The substrate processing apparatus of claim 18, wherein the plurality of grooves formed in at least one of the plurality of reflectors are formed at a certain angle relative to each other on an X-Y plane.
